(19) United States
(12) Patent Application Publication
(10) Pub. No.: US 2018/0371292 A1
(43) Pub. Date: Dec. 27, 2018

(54) BUFFERED CMP POLISHING SOLUTION

(71) Applicant: Rohm and Haas Electronic Materials CMP Holdings, Inc., Newark, DE (US)

(72) Inventor: Hongyu Wang, Wilmington, DE (US)

(21) Appl. No.: 15/991,567

(22) Filed: May 29, 2018

Related U.S. Application Data
(63) Continuation-in-part of application No. 15/628,838, filed on Jun. 21, 2017, now abandoned.

(51) Int. Cl. C09G 1/02; H01L 21/321

(52) U.S. Cl. CPC C09G 1/02; H01L 21/3212

(57) ABSTRACT

The aqueous solution is useful for chemical mechanical polishing a semiconductor substrates. The solution includes by weight percent, 0 to 25 oxidizing agent, 0.05 to 5 guanidine hydrochloride, guanidine sulfate, amino-guanidine hydrochloride, guanidine acetic acid, guanidine carbonate, guanidine nitrate or a combination thereof, 0.1 to 1 glycine, 0.1 to 5 N-methylethanolamine, 0.05 to 5 organic acid complexing agent, 0.05 to 2.2 benzotriazole inhibitor 0 to 5 colloidal silica, and balance water. The solution has a buffering capacity, β of 0.1 to 0.8 with the buffering components being free of alkali, alkaline and transition metal ions.

### CROSS-REFERENCE TO RELATED APPLICATION

This is a continuation-in-part of U.S. Ser. No. 15/628,838, filed Jun. 21, 2017, now pending.

### BACKGROUND

As ultra-large-scale-integrated circuit (ULSI) technology migrates to smaller lines widths, there are new challenges for the integration of conventional chemical mechanical polishing (CMP) processes. In addition, the introduction of low k and ultra-low k dielectric films requires the use of a gentler CMP processes due to the films' low mechanical strength and weak adhesion to adjacent layers. Furthermore, ever-tightening defectivity specifications have placed additional demands on polishing slurries for low k films.

The integration of various low k films into USLIs can also require numerous extra steps and the incorporation of new technologies such as supercritical cleaning, dielectric and metal caps, conformal deposition of barriers and copper, chemical mechanical planarization with low down force and abrasive-free slurries. In addition to these technical options, ULSI fabricators must consider and address process complexity versus yield, reliability, mechanical strength, and performance, namely power dissipation from resistance-capacitance (RC) delay.

The complexities surrounding implementation of low k materials have introduced larger challenges for the barrier CMP process, which will necessitate the ability to control the complicated input variables and achieve a consistent high yield. Tuning process variables can contribute to decreasing polishing variation on the low k film. But the most desirable barrier CMP slurry will incorporate a low k dielectric-specific, surface activated agent that has process tunable performance adjustability. For example, Thomas et al. in US Pat. Pub. No. 2007/0051917, disclose a slurry that adjusts the amount of polyvinyl pyrrolidone and phosphate to control tantalum nitride, copper and carbon doped oxide (CDO) removal rates. Adjusting the amounts of polyvinyl pyrrolidone and silica controls the ratio of tantalum nitride (barrier) to CDO (ultra-low k dielectric) removal rates achieved with the slurry. Unfortunately, these slurries can have incorrect barrier selectivities for some applications. Furthermore, these alkaline slurries contain potassium that can contaminate low-k dielectrics.

There is a demand for a selective barrier polishing solution that can achieve selective barrier removal to dielectrics and low erosion without excessive potassium contamination.

### STATEMENT OF INVENTION

An aspect of the invention provides an aqueous solution useful for chemical mechanical polishing a semiconductor substrate comprising by weight percent, 0 to 25 oxidizing agent, 0.05 to 5 guanidine hydrochloride, guanidine sulfate, amino-guanidine hydrochloride, guanidine acetic acid, guanidine carbonate, guanidine nitrate or a combination thereof, 0.1 to 1 glycine buffering component for buffering the solution, 0.1 to 5 N-methylethanolamine buffering component for buffering the solution, 0.05 to 5 organic acid complexing agent, 0.05 to 2.2 benzotriazole inhibitor, 0 to 5 colloidal silica, and balance water wherein the aqueous solution has a pH of 9.5 to 10.5 and a buffering capacity, 13 of 0.1 to 0.8, each buffering component being free of alkali, alkaline and transition metal ions.

An additional aspect of the invention provides an aqueous solution useful for chemical mechanical polishing a semiconductor substrate comprising by weight percent, 0 to 5 oxidizing agent, 0.1 to 3 guanidine hydrochloride, guanidine carbonate or a combination thereof, 0.1 to 1 glycine buffering component for buffering the solution, 0.5 to 3 N-methylethanolamine buffering component for buffering the solution, 0.1 to 5 organic acid complexing agent, 0.05 to 1 benzotriazole inhibitor, 0.01 to 5 colloidal silica, and balance water wherein the aqueous solution has a pH of 9.8 to 10.2 and a buffering capacity, 13 of 0.2 to 0.7, each buffering component being free of alkali, alkaline and transition metal ions.

### DETAILED DESCRIPTION

It has been discovered that adding a combination of glycine and N-methylethanol amine can buffer a barrier solution without the addition of potassium or an adverse impact upon the semiconductor substrates. For purposes of this specification, semiconductor substrates include wafers having metal conductor interconnects and dielectric materials separated by insulator layers in a manner that can produce specific electrical signals. Furthermore, these solutions allow an increase in abrasive content to further increase the barrier removal rate without a negative impact on low k or copper removal rates. Finally, these solutions provide a platform for adjusting barrier, copper and dielectric removal rates to satisfy a variety of demanding semiconductor applications.

It has been discovered that 0.1 to 1 weight percent glycine buffering component in combination with 0.1 to 5 weight percent N-methylethanolamine buffering component provides effective buffering form alkaline barrier polishing solutions. Advantageously, the solution includes 0.5 to 3 weight percent N-methylethanolamine in combination with the glycine. Most advantageously, the solution includes 0.5 to 3 weight percent N-methylethanolamine in combination with the 0.4 weight percent glycine. This buffering component combination is particularly effective for buffering at alkaline pH levels. This specification expresses all concentrations in weight percent, unless specifically expressed otherwise, such as in parts per million.

The polishing composition can operate at basic pH levels. Advantageously, it has a pH of 9.5 to 10.5 and a balance water. Preferably, the pH is between 9.8 and 10.2 and most preferably, pH is buffered to 10. In addition, the solution most preferably relies upon a balance of deionized water to limit incidental impurities. Most advantageously, the solution contains no source of sodium or potassium ions, such as sodium hydroxide or potassium hydroxide. Preferably, the total potassium ion concentration is less than 5 parts per million or ppm by weight. Most preferably, the total potassium ion concentration is less than 1 parts per million or ppm by weight.

The tantalum barrier removal agent may be guanidine salts and mixture thereof to increase barrier removal rate. Specific examples include at least one of guanidine hydrochloride, guanidine sulfate, amino-guanidine hydrochloride, guanidine acetic acid, guanidine carbonate and guanidine nitrate or a combination thereof. Advantageously, the solution includes guanidine hydrochloride, guanidine carbonate or a combination thereof. Optionally, the solution contains 0.05 to 5 weight percent barrier removal agent. Advantageously, the solution contains 0.1 to 3 weight percent barrier removal agent. Most advantageously, the solution contains 0.2 to 2.5 weight percent barrier removal agent. These barrier removal agents have greater impact with formulations having lower solids concentration. Furthermore, depending upon pH level, increasing oxidizer addition such as hydrogen peroxide may further increase the impact of the barrier removal rate.

Oxidizing agent in an optional amount of 0 to 25 weight percent can facilitate removal of barrier layers, such as tantalum, tantalum nitride, titanium and titanium nitride. Optionally, the solution contains 0 to 20 weight percent oxidizing agent. Most preferably, the solution contains 0 to 5 weight percent oxidizing agent. Suitable oxidizers include, for example, hydrogen peroxide, monopersulfates, iodates, magnesium perphthalate, peracetic acid and other peracids, persulfates, bromates, periodates, nitrates, iron salts, cerium salts, manganese (Mn) (III), Mn (IV) and Mn (VI) salts, silver salts, copper salts, chromium salts, cobalt salts, halogens, hypochlorites, or combinations comprising at least one of the foregoing oxidizers. The preferred oxidizer is hydrogen peroxide. It is to be noted that the oxidizer is typically added to the polishing composition just prior to use and in these instances the oxidizer is contained in a separate package and mixed at the place of use. This is particularly useful for unstable oxidizers, such as, hydrogen peroxide.

Adjusting the amount of oxidizer, such as peroxide, can also control the metal interconnect removal rate. For example, increasing the peroxide concentration increases the copper removal rate. Excessive increases in oxidizer, however, provide an adverse impact upon polishing rate. Most preferably the solution is oxidizer-free.

The barrier metal polishing composition optionally includes colloidal silica for “mechanical” removal of the barrier material. The colloidal silica provides the advantage of eroding low k dielectrics at low rates, colloidal silica represents the preferred abrasive. The colloidal silica abrasive has a concentration in the aqueous phase of the polishing composition of 0 to 5 weight percent. For abrasive-free solutions, a fixed abrasive pad assists with the removal of the barrier layer. Advantageously, the solution contains at least 0.01 weight percent colloidal silica. Preferably, the colloidal silica abrasive concentration is 0.01 to 5 weight percent. Most preferably, the colloidal silica abrasive concentration is 0.05 to 5 weight percent. Typically, increasing abrasive concentration increases the removal rate of barrier materials; and it especially increases the removal rate of tantalum-containing barriers, such as tantalum carbide, tantalum nitride, and tantalum carbide-nitride. For example, if a semiconductor manufacturer desires an increased barrier rate, then increasing the abrasive content can increase the dielectric removal rate to the desired level.

The abrasive preferably has an average particle size of less than 150 nm for preventing excessive metal dishing and dielectric erosion. For purposes of this specification, particle size refers to the colloidal silica's average particle size. Most preferably, the silica has an average particle size of less than 100 nm to further reduce metal dishing and dielectric erosion. In particular, an average abrasive particle size less than 75 nm removes the barrier metal at an acceptable rate without excessive removal of the dielectric material. For example, the least dielectric erosion and metal dishing occur with a colloidal silica having an average particle size of 20 to 75 nm. Decreasing the size of the colloidal silica tends to improve the selectivity of the solution; but it also tends to decrease the barrier removal rate. In addition, the preferred colloidal silica may include additives, such as dispersants to improve the stability of the silica at acidic pH ranges. One such abrasive is colloidal silica that is available from Merck EMD Performance Materials of Puteaux, France.

Optionally, the solution contains 0.05 to 5 weight percent organic acid copper complexing agent to prevent precipitation of nonferrous metals. For example, the solution may contains 0.1 to 5 weight percent organic acid copper complexing agent. Example copper complexing agents include the following: acetic acid, citric acid, ethyl acetoacetate, glycolic acid, lactic acid, malic acid, oxalic acid, saliclylic acid, sodium diethyl dithiocarbamate, succinic acid, tartaric acid, thioglycolic acid, glycine, alanine, aspartic acid, ethylene diamine, trimethyl diamine, malonic acid, gluteric acid, 3-hydroxybutyric acid, propionic acid, phthalic acid, isophthalic acid, 3-hydroxy salicylic acid, 3,5-dihydroxy salicylic acid, gallic acid, gluconic acid, pyrocatechol, pyrogallol, tannic acid, and salts thereof. Preferably, the copper complexing agent is selected from the group consisting of acetic acid, citric acid, ethyl acetoacetate, glycolic acid, lactic acid, malic acid, oxalic acid. Most preferably, the copper complexing agent is citric acid.

An addition of 0.05 to 2.2 weight percent benzotriazole inhibitor decreases removal rate of copper interconnects and protects the copper from static etch. For purposes of this application, copper interconnect refers to interconnects formed with copper having incidental impurities or copper-base alloys. Adjusting the concentration of an inhibitor adjusts the copper interconnect removal rate by protecting the metal from static etch. Preferably the solution contains 0.05 to 1 weight percent benzotriazole inhibitor.

The buffered solution experiences little or no pH drift during extended storage at temperature less than 45° C. For example, the solution drifts less than 0.05 pH units when held at 30° C. for thirty days. Advantageously, the solution drifts less than 0.02 pH units when held at 30° C. for thirty days.

The polishing composition may optionally contain biocides, such as Kordek™ MLX (9.5-9.9% methyl-4-isothiazolin-3-one, 89.1-89.5% water and ≤1.0% related reaction product) manufactured by The Dow Chemical Company, (Kordek is a trademark of The Dow Chemical Company).

Preferably, the solution polishes a semiconductor substrate by applying the solution to a semiconductor substrate by placing 21 kPa or less downward force on a polishing pad. The downward force represents the force of the polishing pad against the semiconductor substrate. The polishing pad may have a circular shape, a belt shape or a web configuration. This low downward force is particularly useful for planarizing the semiconductor substrate to remove a barrier material from the semiconductor substrate. Most preferably, the polishing occurs with a downward force of less than 15 kPa.

The solution provides a tantalum nitride greater than the TEOS rate as measured in Angstroms per minute or a tantalum nitride to carbon-doped oxide selectivity of at least 1 to 1, respectively, as measured in removal rate of Angstroms per minute with a microporous polyurethane polishing pad pressure measured normal to a wafer of less than 20.7 kPa. A particular polishing pad useful for determining selectivity is VisionPad™ 6000 porous polyurethane polishing pad from The Dow Chemical Company. Advantageously, the solution provides a tantalum nitride to carbon-doped oxide selectivity of at least 1.5 to 1, respectively, as measured with a microporous polyurethane polishing pad pressure measured in Angstroms per minute normal to a wafer of less than 20.7 kPa; and most advantageously, this range is at least 2 to 1, respectively.

### Examples

### Solution Preparation Procedure:

Aqueous polishing solution used in this study was prepared according to the following procedure. Benzotriazole or BTA, citric acid, guanidine HCl, glycine and N-methylethanolamine (NMEA) at were added into DI water to specific amounts by weight percent listed in Table 1. Klebosol™ 1598B25 25 nm particle size colloidal silica was then mixed into the solution.

TABLE 1
Table 1. Formulation

| Sam- | | Citric | Guanidine | Gly- | N-methyl- | Colloidal | |
|---|---|---|---|---|---|---|---|
| ple | BTA | Acid | HCl | cine | ethanolamine | Silica | pH |
| 1 | 0.2 | 0.5 | 1.0 | 0.39 | 1.31 | 0.1 | 10.00 |

The polishing test was carried out on an Applied Materials Reflexion™ CMP polishing tool. Pad used was VisionPad™ 6000 porous polyurethane polishing pad from The Dow Chemical Company. The polishing recipe included a 2 psi (13.8 kPa)×93 rpm×87 rpm (down force×table speed×carrier speed). Solution flow rate was 300 ml/min. All polishing was on blanket wafers with the low-k being Black Diamond™ 3 nano-porous low-k dielectric from Applied Materials.

By definition, buffer capacity β is the normality of acid or base needed to cause pH changes for a small unit. It indicates that a higher buffer capacity can provide more pH stability.

β=db/dpH=−da/dpH

The polishing solution has a native pH of 10. It was first titrated with 1.0M KOH in a stepwise format. The pH value was recorded after each addition of KOH. This titration with KOH was finished when pH reached 11.5. A fresh solution sample was then titrated with 1.0M HCl in a stepwise format. The pH value was recorded after each addition of HCl. This titration with HCl was finished when pH reached 8.5.

The normality of KOH and HCl that causes each pH changes during titrations were then calculated. These normality values were then divided by the corresponding delta pH values to generate the β values of Table 2.

TABLE 2

| | | delta HCl or | N number of | |
|---|---|---|---|---|
| pH | delta pH | KOH (ul) | HCl or KOH | Beta |
| 8.39 | 0.1 | 100 | 0.00365 | 0.0365 |
| 8.49 | 0.09 | 100 | 0.00365 | 0.040555556 |
| 8.58 | 0.07 | 100 | 0.00365 | 0.052142857 |
| 8.75 | 0.07 | 100 | 0.00365 | 0.052142857 |
| 8.82 | 0.07 | 100 | 0.00365 | 0.052142857 |
| 8.89 | 0.06 | 100 | 0.00365 | 0.060833333 |
| 8.95 | 0.06 | 100 | 0.00365 | 0.060833333 |
| 9.01 | 0.05 | 100 | 0.00365 | 0.073 |
| 9.06 | 0.05 | 100 | 0.00365 | 0.073 |
| 9.11 | 0.05 | 100 | 0.00365 | 0.073 |
| 9.16 | 0.04 | 100 | 0.00365 | 0.09125 |
| 9.2 | 0.05 | 100 | 0.00365 | 0.073 |
| 9.25 | 0.04 | 100 | 0.00365 | 0.09125 |
| 9.29 | 0.04 | 100 | 0.00365 | 0.09125 |
| 9.33 | 0.03 | 100 | 0.00365 | 0.121666667 |
| 9.36 | 0.03 | 100 | 0.00365 | 0.121666667 |
| 9.43 | 0.03 | 100 | 0.00365 | 0.121666667 |
| 9.46 | 0.03 | 100 | 0.00365 | 0.121666667 |
| 9.49 | 0.03 | 100 | 0.00365 | 0.121666667 |
| 9.52 | 0.03 | 100 | 0.00365 | 0.121666667 |
| 9.55 | 0.03 | 100 | 0.00365 | 0.121666667 |
| 9.58 | 0.02 | 100 | 0.00365 | 0.1825 |
| 9.63 | 0.02 | 100 | 0.00365 | 0.1825 |
| 9.71 | 0.02 | 100 | 0.00365 | 0.1825 |
| 9.73 | 0.02 | 100 | 0.00365 | 0.1825 |
| 9.78 | 0.02 | 100 | 0.00365 | 0.1825 |
| 9.8 | 0.02 | 100 | 0.00365 | 0.1825 |
| 9.82 | 0.02 | 100 | 0.00365 | 0.1825 |
| 9.87 | 0.02 | 100 | 0.00365 | 0.1825 |
| 9.89 | 0.02 | 100 | 0.00365 | 0.1825 |
| 9.91 | 0.02 | 100 | 0.00365 | 0.1825 |
| 9.95 | 0.01 | 50 | 0.001825 | 0.1825 |
| 9.96 | 0.01 | 50 | 0.001825 | 0.1825 |
| 9.97 | 0.01 | 50 | 0.001825 | 0.1825 |
| 9.98 | 0.01 | 50 | 0.001825 | 0.1825 |
| 9.99 | 0.01 | 50 | 0.001825 | 0.1825 |
| 10 | 0.02 | 100 | 0.00365 | 0.1825 |
| 10.02 | 0.01 | 100 | 0.0056 | 0.56 |
| 10.03 | 0.01 | 50 | 0.0028 | 0.28 |
| 10.04 | 0.02 | 100 | 0.0056 | 0.28 |
| 10.06 | 0.02 | 100 | 0.0056 | 0.28 |
| 10.08 | 0.02 | 100 | 0.0056 | 0.28 |
| 10.1 | 0.02 | 100 | 0.0056 | 0.28 |
| 10.12 | 0.02 | 100 | 0.0056 | 0.28 |
| 10.14 | 0.02 | 100 | 0.0056 | 0.28 |
| 10.16 | 0.02 | 100 | 0.0056 | 0.28 |
| 10.18 | 0.02 | 100 | 0.0056 | 0.28 |
| 10.2 | 0.02 | 100 | 0.0056 | 0.28 |
| 10.22 | 0.02 | 100 | 0.0056 | 0.28 |
| 10.24 | 0.02 | 100 | 0.0056 | 0.28 |
| 10.26 | 0.02 | 100 | 0.0056 | 0.28 |
| 10.28 | 0.02 | 100 | 0.0056 | 0.28 |
| 10.3 | 0.02 | 100 | 0.0056 | 0.28 |
| 10.32 | 0.02 | 100 | 0.0056 | 0.28 |
| 10.34 | 0.02 | 100 | 0.0056 | 0.28 |
| 10.36 | 0.02 | 100 | 0.0056 | 0.28 |
| 10.38 | 0.02 | 100 | 0.0056 | 0.28 |
| 10.4 | 0.03 | 100 | 0.0056 | 0.186666667 |
| 10.47 | 0.03 | 100 | 0.0056 | 0.186666667 |
| 10.54 | 0.03 | 100 | 0.0056 | 0.186666667 |
| 10.59 | 0.03 | 100 | 0.0056 | 0.186666667 |
| 10.64 | 0.03 | 100 | 0.0056 | 0.186666667 |
| 10.67 | 0.03 | 100 | 0.0056 | 0.186666667 |
| 10.7 | 0.03 | 100 | 0.0056 | 0.186666667 |
| 10.73 | 0.03 | 100 | 0.0056 | 0.186666667 |
| 10.76 | 0.03 | 100 | 0.0056 | 0.186666667 |
| 10.79 | 0.04 | 100 | 0.0056 | 0.14 |
| 10.86 | 0.04 | 100 | 0.0056 | 0.14 |
| 10.9 | 0.04 | 100 | 0.0056 | 0.14 |
| 10.94 | 0.04 | 100 | 0.0056 | 0.14 |
| 10.98 | 0.04 | 100 | 0.0056 | 0.14 |
| 11.02 | 0.05 | 100 | 0.0056 | 0.112 |
| 11.07 | 0.05 | 100 | 0.0056 | 0.112 |
| 11.12 | 0.05 | 100 | 0.0056 | 0.112 |
| 11.17 | 0.06 | 100 | 0.0056 | 0.093333333 |
| 11.23 | 0.06 | 100 | 0.0056 | 0.093333333 |
| 11.29 | 0.06 | 100 | 0.0056 | 0.093333333 |
| 11.35 | 0.07 | 100 | 0.0056 | 0.08 |
| 11.42 | 0.07 | 100 | 0.0056 | 0.08 |
| 11.49 | 0.08 | 100 | 0.0056 | 0.07 |

Table 2. Buffer Capacity.

Table 2 illustrates a strong buffer capacity from pH 9.5 to 10.5 (β=0.12 to 0.56) with a maximum buffer capacity at pH 10 to 10.5 (β=0.19 to 0.56). It is possible to increase buffering capacity, β, by increasing the concentration of the buffering components, N-methylethanolamine and glycine. Typical polishing slurries have a buffer capacity, β of 0.1 to 0.8. Preferably, polishing slurries have a buffer capacity, β of 0.2 to 0.7. Most preferably, polishing slurries have a buffer capacity, β of 0.25 to 0.6.

TABLE 3
Table 3. Varied Abrasive Loading.

| Abrasive | Film removal rate (Å/min) | | | | | |
|---|---|---|---|---|---|---|
| (%) | TEOS | Low-k | TaN | Cu | TiN | Co |
| 0.05 | 11 | 71 | 60 | 172 | 46 | 146 |
| 0.1 | 17 | 118 | 100 | 179 | 83 | 161 |
| 0.25 | 29 | 209 | 157 | 183 | 176 | 162 |
| 0.5 | 46 | 333 | 184 | 188 | 208 | 167 |
| 1 | 74 | 491 | 215 | 179 | 242 | 173 |

From the polishing results of Table 3 above, it is observed that the polishing solution, even with varied abrasive levels provides selective removal for low-K dielectric, TaN, Cu, TiN and Co films and stops on TEOS films. This is ideal for any processes that requires a hard stop on TEOS. In addition, for integration schemes that do not involve TEOS, the selectivity of films to low k dielectric films can be tuned via dilution for enhanced low-k dielectric removal for better topography correction. See Table 4.

TABLE 4
Table 4. Film Selectivity

| Abrasive | Selectivity | | | | | | | |
|---|---|---|---|---|---|---|---|---|
| (%) | TaN:TEOS | TaN:Low-k | Cu:TEOS | Cu:Low-k | TiN:TEOS | TiN:Low-k | Co:TEOS | Co:Low-k |
| 0.05 | 5.45 | 0.85 | 15.64 | 2.42 | 4.18 | 0.65 | 13.27 | 2.06 |
| 0.1 | 5.88 | 0.85 | 10.53 | 1.52 | 4.88 | 0.70 | 9.47 | 1.36 |
| 0.25 | 5.41 | 0.75 | 6.31 | 0.88 | 6.07 | 0.84 | 5.59 | 0.78 |
| 0.5 | 4.00 | 0.55 | 4.09 | 0.56 | 4.52 | 0.62 | 3.63 | 0.50 |
| 1 | 2.91 | 0.44 | 2.42 | 0.36 | 3.27 | 0.49 | 2.34 | 0.35 |

The buffered polishing solution containing N-methylethanolamine (NMEA) and glycine provides excellent buffering for alkaline barrier polishing. These buffering components are free of alkali, alkaline and transition metal ions. Preferably, the entire polishing solution is free of alkali, alkaline and transition metal ions. Furthermore, it provides effective buffer capacity while avoiding the deliberate addition of KOH. The elimination of potassium ions limits deleterious poisoning of semiconductor dielectrics.

We claim:

1. An aqueous solution useful for chemical mechanical polishing a semiconductor substrate comprising by weight percent,
0 to 25 oxidizing agent,
0.05 to 5 guanidine hydrochloride, guanidine sulfate, amino-guanidine hydrochloride, guanidine acetic acid, guanidine carbonate, guanidine nitrate or a combination thereof,
0.1 to 1 glycine buffering component for buffering the solution,
0.1 to 5 N-methylethanolamine buffering component for buffering the solution,
0.05 to 5 organic acid complexing agent,
0.05 to 2.2 benzotriazole inhibitor,
0 to 5 colloidal silica, and
balance water wherein the aqueous solution has a pH of 9.5 to 10.5 and a buffering capacity, β of 0.1 to 0.8, each buffering component being free of alkali, alkaline and transition metal ions.

2. The aqueous solution of claim 1 wherein the solution is oxidizer-free.

3. The aqueous solution of claim 1 containing at least 0.01 weight percent colloidal silica.

4. The aqueous solution of claim 1 wherein the solution is buffered to a pH of 10.

5. The aqueous solution of claim 1 wherein organic acid complexing agent is citric acid.

6. An aqueous solution useful for chemical mechanical polishing a semiconductor substrate comprising by weight percent,
0 to 5 oxidizing agent,
0.1 to 3 guanidine hydrochloride, guanidine carbonate or a combination thereof,
0.1 to 1 glycine buffering component for buffering the solution,
0.5 to 3 N-methylethanolamine buffering component for buffering the solution,
0.1 to 5 organic acid complexing agent,
0.05 to 1 benzotriazole inhibitor,
0.01 to 5 colloidal silica, and
balance water wherein the aqueous solution has a pH of 9.8 to 10.2 and a buffering capacity, β of 0.2 to 0.7, each buffering component being free of alkali, alkaline and transition metal ions.

7. The aqueous solution of claim 6 wherein the solution is oxidizer-free.

8. The aqueous solution of claim 6 wherein the colloidal silica is 0.05 to 5.

9. The aqueous solution of claim 6 wherein the solution is buffered to a pH of 10.

10. The aqueous solution of claim 6 wherein organic acid complexing agent is citric acid.
